(19) United States
(12) Patent Application Publication
(10) Pub. No.: US 2026/0076118 A1
(43) Pub. Date: Mar. 12, 2026

(54) METHOD FOR ETCHING FEATURES IN A STACK

(71) Applicant: Lam Research Corporation, Fremont, CA (US)

(72) Inventors: Leonid BELAU, Pleasanton, CA (US); Eric A. HUDSON, Berkeley, CA (US)

(21) Appl. No.: 19/107,844

(22) PCT Filed: Sep. 7, 2023
(86) PCT No.: PCT/US2023/073655

§ 371 Date: Feb. 28, 2025

Related U.S. Application Data
(60) Provisional application No. 63/406,183, filed on Sep. 13, 2022.

(51) Int. Cl. H01L 21/311; H01J 37/305; H01L 21/67

(52) U.S. Cl. CPC H10P 50/283; H01J 37/3053; H10P 50/73; H10P 72/0421

(57) ABSTRACT

A method for etching features in a stack comprising a silicon oxide layer below a mask is provided. A substrate support for supporting the stack in an etch chamber is cooled to a temperature below 0° C. An etch gas comprising a halogen containing component and a phosphorous containing component is provided. A plasma is generated from the etch gas. A bias is provided to accelerate ions from the plasma to the stack. Features are selectively etched in the stack with respect to the mask.

### CROSS-REFERENCE TO RELATED APPLICATION

This application claims the benefit of priority of U.S. Application No. 63/406,183, filed Sep. 13, 2022, which is incorporated herein by reference for all purposes.

### BACKGROUND

The disclosure relates to a method of forming semiconductor devices on a semiconductor wafer. More specifically, the disclosure relates to etching a stack in the formation of memory or other semiconductor devices.

In forming semiconductor devices, etch layers may be etched to form memory holes or lines. Some semiconductor devices may be formed by etching a stack of bilayers of silicon oxide and silicon nitride (ONON). Such stacks may be used in memory applications, such as in forming dynamic random access memory (DRAM) and three dimensional “negative and” gates (3D NAND).

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack comprising a silicon oxide layer below a mask is provided. A substrate support for supporting the stack in an etch chamber is cooled to a temperature below 0° C. An etch gas comprising a halogen containing component and a phosphorous containing component is provided. A plasma is generated from the etch gas. A bias is provided to accelerate ions from the plasma to the stack. Features are selectively etched in the stack with respect to the mask.

In another manifestation, an apparatus for processing a stack over a substrate with at least one of a silicon oxide layer and silicon nitride layer below a mask is provided. An etch chamber is provided. A substrate support supports a substrate inside the etch chamber. A temperature controller controls a temperature of the substrate support. An electrode provides RF power inside the etch chamber. An RF power source provides RF power to the electrode. A gas source provides an etch gas into the etch chamber where the gas source comprises a halogen containing component source and an HF gas source.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-B are schematic cross-sectional views of a stack processed according to an embodiment.

FIG. 3 is a schematic view of an etch chamber that may be used in an embodiment.

FIG. 4 is a schematic view of a computer system that may be used in practicing an embodiment.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

There is a significant challenge to control profile in the very high aspect ratio contact dielectric etch, specifically during cryogenic etching of 3D NAND pillar structure: large bow CD with small bottom CD. This is likely due to increased by-product accumulation close to the etch front that slows down a SiO₂ reactive ion etch (RIE). The most common method to increase the etch rate (ER) for a high aspect ratio is to increase ion energy and ion flux. This results in worse bow CD control (larger bow). Another common practice to increase bottom CD and ER is modifying plasma chemistry. This approach causes other tradeoffs such as bow enlargement, capping, or excessive contact twisting.

In some embodiments, the etch front surface is modified to enhance the etching of silicon oxide (SiO₂, also known as SiO) and silicon nitride (Si₃N₄, also known as SiN). Some embodiments add phosphorous (P) containing precursors to a plasma. It is believed that P containing precursors cause P-doping of the SiO₂ and Si₃N₄ material. Doped SiO₂ material will have reduced activation energy for RIE. Thus even low energy ions from the plasma can contribute to the etch. Phosphine (PH₃) and phosphorous trifluoride (PF₃) are the two major compounds that can be used in some embodiments as P containing precursors. Some embodiments may use other compounds such as phosphorous trichloride (PCl₃), phosphorous tribromide (PBr₃), phosphorous oxyfluoride (POF₃), or phosphorous triiodide (PI₃), which are liquid or solid at room temperature and therefore are harder to productize or may use phosphorus pentafluoride (PF₅).

Reduction of the etch activation energy of SiO₂ and Si₃N₄ by phosphorus doping for RIE will help to maintain a high ONON pillar ER even at a high aspect ratio. This will enable more efficient utilization of reactive ions delivered to the etch front. Reducing ER dependence on high-energy ions to control pillar profile (especially needed for etch front control and twisting) can enable a new operation process power regime that will rely more on high ion flux with reduced ion energy, i.e. increased radio frequency (RF) average power at reduced peak power in the pulsed capacitively coupled plasma (CCP) etcher. Due to the hardware power limitation, one can either increase ion energy or ion flux. Some embodiments make the silicon oxide etch more chemical in nature and more similar to a silicon nitride etch, providing a more uniform ONON etching.

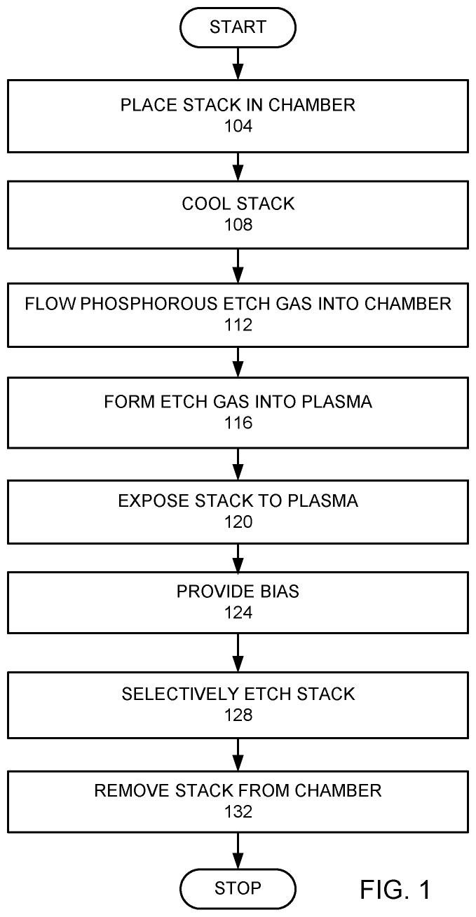

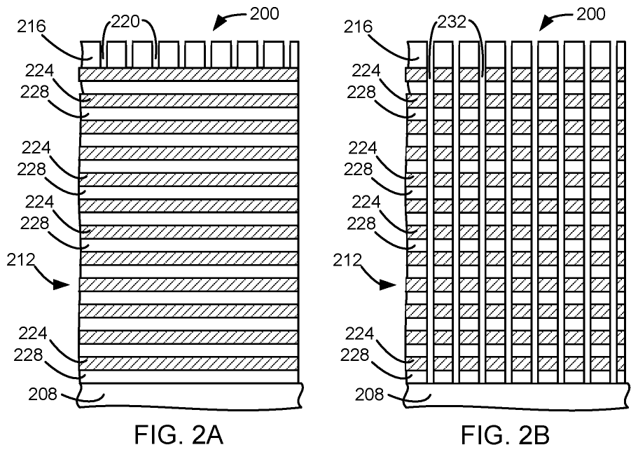

To facilitate understanding, FIG. 1 is a high level flow chart that may be used in some embodiments. In some embodiments, a stack is placed in an etch chamber on a substrate support (step 104). In some embodiments, the stack is disposed below a carbon containing patterned mask. In some embodiments, the carbon containing mask is an amorphous carbon mask. FIG. 2A is a schematic cross-sectional view of a stack 200 used in an embodiment. In some embodiments, the stack comprises a substrate 208 under a plurality of bilayers 212, which is disposed below a carbon containing patterned mask 216. One or more layers may be disposed between the substrate 208 and the plurality of bilayers 212 or the plurality of bilayers 212 and the carbon containing patterned mask 216. However, some embodiments do not have a silicon containing mask above the plurality of bilayers 212 or above the carbon containing patterned mask 216. The carbon containing patterned mask 216 may be amorphous carbon. In some embodiments, the patterned mask pattern provides mask features 220 for high aspect ratio contacts. In some embodiments, the mask features are formed before the substrate is placed in the etch chamber. In other embodiments, the mask features 220 are formed while the substrate is in the etch chamber. In some embodiments, the plurality of bilayers 212 are bilayers of a layer of silicon oxide 224 and a layer of silicon nitride 228.

After the stack 200 has been placed into an etch chamber, the stack is cooled to a temperature below 0° (step 108). In some embodiments, the stack is cooled to a temperature below −40°.

An etch gas comprising a halogen containing component and a phosphorous containing component is flowed into the etch chamber (step 112). In some embodiments, the etch gas comprises a halogen containing component, a phosphorous containing component, a hydrogen containing component, a hydrocarbon containing component, and a fluorocarbon containing component. In some embodiments, the halogen containing component comprises at least one of chlorohydrocarbon CₓH_{y}Cl_{z}, silicon tetrachloride (SiCl₄), bromine trichloride (BCl₃), nitrogen trifluoride (NF₃), C₄F₈, octafluoropropane (C₃F₈), hexafluoro-1,3-butadiene (C₄F6), sulfur hexafluoride (SF₆), carbon tetrafluoride (CF₄), chlorine (Cl₂), hydrogen bromide (HBr), trifluoroiodomethane (CF₃I), fluoromethane (CH₃F), difluoromethane (CH₂F₂), hydrochloric acid (HCl), and trifluoromethane (CHF₃). In some embodiments, the etch gas further comprises an inert gas, such as argon (Ar), helium (He), krypton (Kr), neon (Ne), xenon (Xe), or nitrogen (N₂). In some embodiments, the inert gas provides ions for ion bombardment to facilitate etching and therefore may be an inert bombardment gas. In some embodiments, the etch gas is oxygen free and free from both octafluorocyclobutane (C₄F₈) and hexafluorocyclobutene (C₄F₆). In some embodiments, the etch gas further comprises at least one of methane (CH₄), and hydrogen gas (H₂). In some embodiments, the phosphorous containing component is at least one of PH₃, PF₃, PCl₃, PBr₃, POF₃, and PI₃. In some embodiments, an example of an etch gas is 5-120 sccm NF₃, 50-400 sccm H₂, 0-100 sccm CH₃F, 1-100 sccm PH₃, 0-100 sccm Cl₂, 0-100 sccm HBr, and 20-200 sccm CH₂F₂. In this example, a pressure of 5 to 60 mTorr is provided. In some embodiments, the halogen containing component may comprise a fluorine, chlorine, or bromine containing component.

The etch gas is formed into an etch plasma (step 116). This may be accomplished by providing an excitation RF with a frequency of 60 megahertz (MHz) at 200 to 15000 watts. In some embodiments, the RF power is in the range of 0 to 25000 watts at a frequency of 60 MHz. The stack 200 is exposed to the plasma (step 120). A bias with a magnitude in the range of 200 volts to 15000 volts is provided (step 124). In some embodiments, an RF power that is either continuous or pulsed RF power with a peak power in the range of 3 kW to 150 kW may be used for both excitation RF power using a higher frequency and bias RF power using a lower frequency. The bias causes ions to be accelerated to the stack 200 causing the selective etching of high aspect ratio etch features into the stack 200 with respect to the carbon containing patterned mask (step 128). The plasma is maintained for 180 to 3600 seconds. The etch is able to etch both the silicon oxide and silicon nitride layers. After the etch is completed, the substrate is then removed from the etch chamber (step 132).

FIG. 2B is a cross-sectional view of the stack 200 after the contacts 232 have been etched. The contacts are high aspect ratio contacts. Preferably, the contacts have an etch depth to feature CD width aspect ratio of greater than 30:1. More preferably, the high aspect ratio contacts have a height to CD width ratio of greater than 40:1. More preferably, the high aspect ratio contacts have a height to CD width ratio of greater than 100:1.

The etch process is able to selectively etch the silicon oxide and silicon nitride layers with respect to amorphous carbon with a selectivity of greater than 3:1 while etching high aspect ratio features. The resulting features also have reduced bowing, striation, distorting, capping, and tapering. In addition, this embodiment allows the use of a carbon containing patterned mask, such as amorphous carbon, without requiring a silicon containing mask such as polysilicon, which reduces costs and defects.

Previous processes that use an etch, where the stack is processed at a temperature above 0° C., relied on a fluorocarbon chemistry to etch and provide sidewall protection. Such a process resulted in a mask to silicon oxide and silicon nitride etch selectivity of less than 3:1. Sidewall protection was provided by polymer deposition, which is controlled by the concentration of carbon, where a higher concentration of carbon increases sidewall deposition, and by oxygen, where a higher concentration of oxygen consumes the deposited polymer. The higher concentration of oxygen also increased the consumption of the mask. Some previous processes used a silicon containing mask.

Some embodiments increase the etch rate and improve contact shape/striation compared to a conventional approach. Without being bound by theory, it is believed that the addition of a phosphorous containing component to the etch gas causes phosphorous dopant to deposit in the silicon oxide and silicon nitride containing layers. The phosphorous dopant lowers the activation energy required to etch the silicon oxide containing layers so that silicon oxide is more easily etched and so that lower energy ions are sufficient. Providing lower energy ions for etching results in less bowing and the reduction of other etch complications caused by high energy ions. The phosphorous dopant may also lower the activation energy required to etch silicon nitride. However, the phosphorous dopant lowers the activation energy for silicon oxide more than the phosphorous lowers the activation energy for silicon nitride. In the prior art, silicon oxide was more difficult to etch than silicon nitride, causing an uneven etch of ONON stacks. Providing the phosphorous dopant allows for a more even etch of ONON.

In some embodiments, the electrostatic chuck is cooled to a temperature below 0° C. In some embodiments, the chuck is cooled to a temperature below −10° C. In some embodiments, the chuck is cooled to a temperature below −20° C. In some embodiments, the chuck is cooled to a temperature between −80° C. to 0° C. to provide an improved process. In some embodiments, the stack is cooled to a temperature between −60° C. to −20° C.

In some embodiments, the stack comprises one or more layers of at least one of silicon oxide and silicon nitride. In some embodiments, the stack is a single layer of silicon oxide or silicon nitride. In some embodiments, the stack comprises alternating layers of silicon oxide and polysilicon (OPOP).

In some embodiments, the ONON stack may be etched to form contact holes, channel holes, or trenches in making a 3D NAND memory device. Other embodiments may etch OPOP (alternating layers of SiO₂ and polysilicon) stacks to form contact holes, channel holes, or trenches in making 3D NAND memory devices. Other embodiments may be used for DRAM Capacitor etching. The capacitor etch may have a depth of 1.5 microns with a tight CD providing a high aspect ratio feature in silicon oxide. Some embodiments provide etch features with a height to width ratio greater than 10:1. Some embodiments provide for a CD less than 50 nm with an etch depth of greater than 20 microns, providing features with a depth to width aspect ratio of at least 4000:1. In some embodiments, the etch depth is greater than 3 microns. Some embodiments allow the etching of at least 48 bilayers of silicon oxide and silicon nitride in a single etch step using a single amorphous carbon mask with a thickness of less than 1 micron.

In some embodiments, the etch gas may further comprise a hydrofluorocarbon containing component, such as difluoromethane (CH₂F₂). The hydrofluorocarbon containing component may be used to promote the etching of silicon nitride by providing passivation at cryogenic temperatures to control CD.

In some embodiments, the providing the etch gas and the ion etching may be provided as sequential steps in a cyclical process. Providing the etch gas simultaneously with the ion etching provides a faster process than the sequential cyclical process.

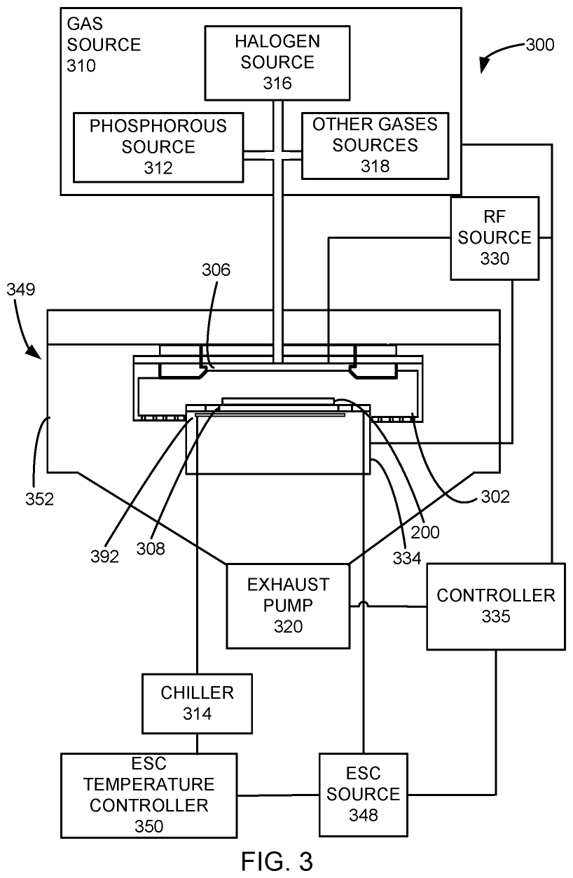

FIG. 3 is a schematic view of an etch reactor that may be used in an embodiment. In one or more embodiments, an etch reactor 300 comprises a gas distribution plate 306 providing a gas inlet and an electrostatic chuck (ESC) 308, within an etch chamber 349, enclosed by a chamber wall 352. Within the etch chamber 349, a stack 200 is positioned over the ESC 308, where the ESC 308 acts as a substrate support. The ESC 308 may provide a bias from the ESC source 348. An etch gas source 310 is connected to the etch chamber 349 through the gas distribution plate 306. In some embodiments, the etch gas source 310 comprises a phosphorous containing component source 312, a halogen containing component source, and a source of other gases 318, such as a hydrogen containing component source, and a fluorocarbon containing component source. An ESC temperature controller 350 is connected to a chiller 314. The chiller 314 is able to cool the ESC 308 to a temperature of less than 0° C. In this embodiment, the chiller 314 provides a coolant to channels 392 in or near the ESC 308. A radio frequency (RF) power source 330 provides RF power to a lower electrode and/or an upper electrode, which in this embodiment are the ESC 308 and the gas distribution plate 306. In some embodiments, a non-RF power source, such as a pulsed DC power source, may replace or be used with the RF power source 330 for controlling the plasma. In an exemplary embodiment, 400 kilohertz (kHz), 60 megahertz (MHz), and optionally 2 MHz, 27 MHz power sources make up the RF power source 330 and the ESC source 348. In this embodiment, the upper electrode is grounded. In this embodiment, one generator is provided for each frequency. In other embodiments, the generators may be in separate RF sources or separate RF generators may be connected to different electrodes. For example, the upper electrode may have inner and outer electrodes connected to different RF sources. Other arrangements of RF sources and electrodes may be used in other embodiments. The RF power may be continuous or pulsed. A controller 335 is controllably connected to the RF power source 330, the ESC source 348, an exhaust pump 320, and the etch gas source 310. An example of such an etch chamber is the Exelan Flex® dielectric etch system or Vantex® dielectric etch system manufactured by Lam Research Corporation of Fremont, CA. The etch chamber can be a CCP (capacitively coupled plasma) reactor or an ICP (inductively coupled plasma) reactor, where the electrode may be a coil.

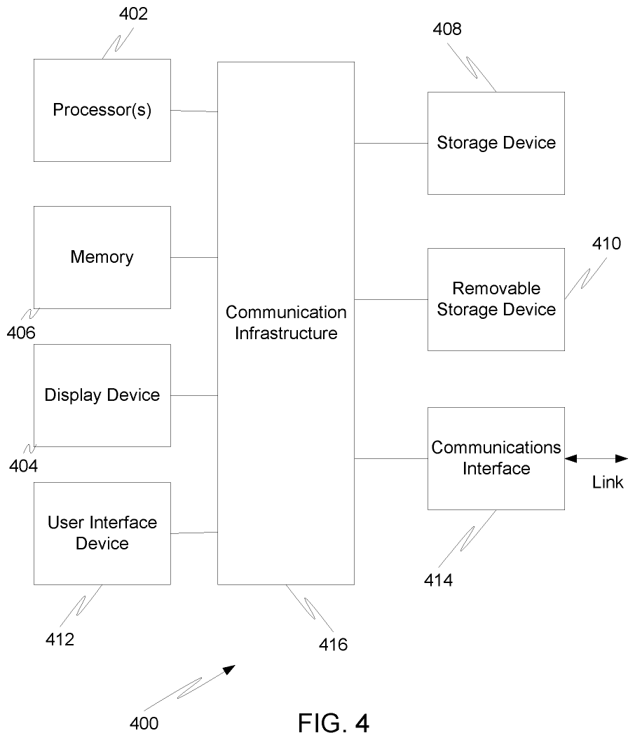

FIG. 4 is a high level block diagram showing a computer system 400, which is suitable for implementing a controller 335 used in embodiments. The computer system may have many physical forms ranging from an integrated circuit, a printed circuit board, and a small handheld device up to a huge supercomputer. The computer system 400 includes one or more processors 402 and further can include an electronic display device 404 (for displaying graphics, text, and other data), a main memory 406 (e.g., random access memory (RAM)), a storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

The information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

In some embodiments, liquid nitrogen is used as a coolant that is flowed through the ESC 308 to provide cooling. In other embodiments, liquid Vertel Sinera™ manufactured by DuPont Corporation of Wilmington, DE may be used as the coolant.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack comprising a silicon oxide layer below a mask, comprising:
cooling a substrate support for supporting the stack in an etch chamber to a temperature below 0° C.;
providing an etch gas comprising a halogen containing component and a phosphorous containing component;
generating a plasma from the etch gas;
providing a bias to accelerate ions from the plasma to the stack; and
selectively etching features in the stack with respect to the mask.

2. The method, as recited in claim 1, wherein the etch gas further comprises a hydrogen containing component, a hydrocarbon containing component, and a fluorocarbon containing component.

3. The method, as recited in claim 1, wherein the mask is a carbon containing mask.

4. The method, as recited in claim 3, wherein the carbon containing mask is amorphous carbon.

5. The method, as recited in claim 1, wherein the etch gas is oxygen free and free from both C₄F₈ and C₄F₆.

6. The method, as recited in claim 1, wherein the halogen containing component, comprises at least one of chlorohydrocarbon, SiCl₄, BCl₃, NF₃, C₄F₈, C₃F₈, C₄F₆, SF₆, CF₄, Cl₂, HBr, CF₃I, CH₃F, CH₂F₂, CHF₃, and HCl.

7. The method, as recited in claim 1, wherein the etch gas further comprises at least one of H₂, O₂, and CH₄.

8. The method, as recited in claim 1, wherein the cooling the substrate support for supporting the stack in an etch chamber to a temperature below 0° C., further comprises cooling the substrate support to a temperature below −10° C.

9. The method, as recited in claim 1, wherein the mask is a carbon containing mask and the stack comprises a plurality of alternating silicon oxide layers or silicon nitride layers.

10. The method, as recited in claim 1, further comprising providing an RF power with a peak power in a range of 3 kW to 150 kW.

11. The method, as recited in claim 1, wherein the phosphorous containing component comprises at least one of PH₃, PF₃, PCl₃, PBr₃, POF₃, and PI₃.

12. The method, as recited in claim 1, wherein the phosphorous containing component comprises at least one of PH₃ and PF₃.

13. The method, as recited in claim 1, wherein the etch gas further comprises an inert gas comprising at least one of He, Ne, Ar, Kr, Xe, and N₂.

14. The method, as recited in claim 1, wherein the mask is a carbon containing mask and wherein the stack includes a plurality of alternating silicon oxide and polysilicon layers.

15. The method, as recited in claim 1, wherein the features have a height to width ratio greater than 10:1.

16. An apparatus for processing a stack over a substrate with at least one silicon oxide layer, comprising:
an etch chamber;
a substrate support for supporting a substrate inside the etch chamber;
a temperature controller for controlling a temperature of the substrate support;
an electrode for providing RF power inside the etch chamber;
an RF power source for providing RF power to the electrode; and
a gas source that provides an etch gas into the etch chamber, the gas source comprising:
a halogen containing component source; and
a phosphorous containing component source.

17. The apparatus, as recited in claim 16, further comprising a controller controllably connected to the gas source, the RF power source, and the temperature controller, comprising:
a processor; and
computer readable media with computer readable code, wherein the computer readable code comprises:
computer readable code for cooling the substrate support to a temperature of no more than 0° C.;
computer readable code for providing an etch gas comprising a halogen containing component from the halogen containing component source and a phosphorous containing component from the phosphorous containing component source;
computer readable code for providing RF power for generating a plasma from the etch gas; and
computer readable code for generating a bias.

18. The apparatus, as recited in claim 17, wherein the gas source further comprises:
a hydrogen containing component source; and
a fluorocarbon containing component source.

19. The apparatus, as recited in claim 18, wherein the computer readable code for providing the etch gas further comprises computer readable code for providing a hydrogen containing component from the hydrogen containing component source and a fluorocarbon containing component from the fluorocarbon containing component source.

20. The apparatus, as recited in claim 16, further comprising a non-RF power source for controlling plasma in the etch chamber.
